(19) United States
(12) Patent Application Publication
(10) Pub. No.: US 2023/0311204 A1
(43) Pub. Date: Oct. 5, 2023

(54) ELECTRICALLY CONDUCTIVE FILLERS WITH IMPROVED MICROWAVE SHIELDING PERFORMANCE

(71) Applicant: OERLIKON METCO (US) INC., Westbury, NY (US)

(72) Inventor: Alex IASNIKOV, St. Albert (CA)

(73) Assignee: OERLIKON METCO (US) INC., Westbury, NY (US)

(21) Appl. No.: 18/022,583

(22) PCT Filed: Nov. 19, 2021
(86) PCT No.: PCT/US2021/060108

§ 371 Date: Feb. 22, 2023

Related U.S. Application Data
(60) Provisional application No. 63/116,434, filed on Nov. 20, 2020.

(51) Int. Cl. B22F 1/18; H05K 9/00; C23C 16/22

(52) U.S. Cl. CPC B22F 1/18; H05K 9/0083; C23C 16/22; B22F 2301/10; B22F 2301/15; B22F 2302/40; B22F 2303/40

(57) ABSTRACT

An electrically conductive composite powder is provided for microwave shielding applications. The electrically conductive composite powder includes a core of particles formed from a material having a low density of <5 g/cm³ and a high dielectric constant of ≥10; an intermediate layer coated onto the core of particles, wherein said intermediate layer has a high electrical conductivity of >5.90×10⁻⁸ Ohm*m at 20° C.; and an outer layer that is deposited onto the intermediate layer, said outer layer comprising a material having a high oxidation and corrosion resistance of >−0.2V galvanic potential in seawater as measured via ASTM G82. The electrically conductive composite powder exhibits excellent microwave shielding performance, while also being substantially lower in cost that conventional Ag/Ni shields. The electrically conductive composite powder can be used across a broad microwave frequency range.

This application claims priority to U.S. Provisional Application No. 63/116,434, filed Nov. 20, 2020. The disclosure of this application is herein incorporated by reference in its entirety.

### BACKGROUND OF THE INVENTION

### 1. Field of the Disclosure

Example embodiments generally relate to electrically conductive fillers having improved microwave shielding properties. In particular, example embodiments relate to nickel coated graphite (Ni/C) based electrically conductive fillers that have absorptive properties to improve shielding performance

### 2. Background Information

During normal operation, electronic equipment generates undesirable electromagnetic energy that can interfere with the operation of proximately located electronic equipment due to electromagnetic interference (EMI). To minimize the problems associated with EMI, electrically conductive materials can be used to shield EMI. Conductive materials having improved EMI shielding performance above 50 gigahertz (GHz) for automotive radar and future 5G and 6G devices would be desirable. Conventional shields to reduce EMI can be constructed by conductive materials having silver coated nickel (Ag/Ni) powder. These Ag/Ni shields may be effective to reduce EMI but would be expensive and difficult to compound in polymers because it is a heavy material.

Alternative shields constructed of conductive materials having Ni/C would be cheaper and lighter, but the shielding performance would decline above 50 GHz. Conductive materials having Ni/C exhibit reduced shielding performance above 50 GHz because its shielding performance depends on the magnetic permeability which exhibits dispersion with increasing frequency. More specifically, the permeability of nickel is reduced from 200 to 1-10 in the GHz range. Thus, new electrically conductive materials are needed to improve EMI shielding performance.

### SUMMARY

Desirable shielding performance of electrically conductive materials generally requires either high electrical conductivity or high magnetic permeability. Conventional shields constructed by conductive materials having silver coated nickel powder can be used to suppress EMI in the GHz range which is attributed to the high electrical conductivity of silver. Electrically, copper and silver behave similarly. Unlike silver, copper has poor corrosion and oxidation resistance which makes it unsuitable for use as a conductive material.

Example embodiments of the present disclosure relate to an electrically conductive composite powder. In example embodiments, a core of particles is coated with an intermediate layer and an outer layer is deposited onto the intermediate layer. In embodiments, the core of particles is formed from a material having a low density and a dielectric constant >10. In other embodiments, the intermediate layer includes a material having a high electrical conductivity. In yet other embodiments, the outer layer includes a material having a high corrosion and oxidation resistance.

Preferred embodiments of the present disclosure relate to a nickel coated graphite (Ni/C) based electrically conductive filler. In example embodiments, it is preferable to add at least one layer of copper to the Ni/C based electrically conductive filler. The addition of a copper layer increases the shielding performance of the Ni/C based electrically conductive filler to a similar effectiveness as conventional Ag/Ni shields, while substantially reducing the cost. The nickel in the Ni/C based electrically conductive filler acts as a corrosion and oxidation resistant layer that protects copper from corrosion.

In example embodiments, a powder of the Ni/C based electrically conductive filler may be produced with a density that is 30% less than conventional Ag/Ni conductive materials because the graphite core has a density lower than silver and nickel. In another example embodiment, the Ni/C based electrically conductive filler includes a graphite core of particles, a copper layer coated onto the graphite core of particles, and a nickel layer that is deposited onto the copper layer. In example embodiments, the copper coating layer deposed below the nickel layer in the Ni/C based electrically conductive filler improves shielding performance above 40 GHz.

The Ni/C based electrically conductive filler of the present disclosure addresses problems, including high cost and high density, of conventional Ag/Ni shields. Moreover, copper provides a similar shielding performance as silver with the same coating thickness because the electrical conductivity of copper is only 4% less than silver. However, nickel exhibits a higher corrosion and oxidation resistance performance than copper and, thus, a nickel coating protects copper from corrosion and produces particles with higher corrosion and oxidation resistance. Accordingly, the Ni/C based electrically conductive filler of the present disclosure improves microwave shielding performance in a 40-300 GHZ range. Preferably, the Ni/C based electrically conductive filler of the present disclosure improves microwave shielding performance in a 40-100 GHz range. More preferably, the Ni/C based electrically conductive filler of the present disclosure improves microwave shielding performance in a 40-100 GHz range.

### BRIEF DESCRIPTION OF THE DRAWINGS

The application file contains at least one drawing executed in color. Copies of this patent application publication with color drawing(s) will be provided by the Office upon request and payment of the necessary fee.

The present disclosure is further described in the detailed description which follows, in reference to the noted plurality of drawings, by way of non-limiting examples of preferred embodiments of the present disclosure.

FIG. 1 illustrates a cross section of an electrically conductive filler, according to various embodiments.

### DETAILED DESCRIPTION

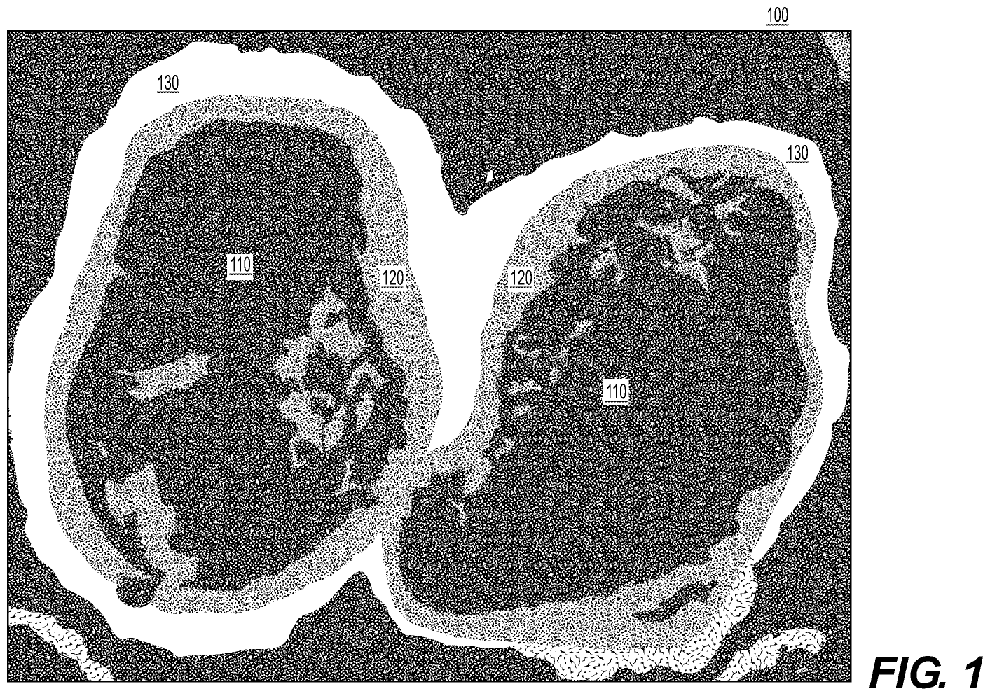

FIG. 1 illustrates a cross section of an electrically conductive filler 100, according to various embodiments. In FIG. 1, the electrically conductive filler 100 includes core particles 110, an intermediate layer 120 coated onto the core particles 110, and an outer layer 130 that is deposited onto the intermediate layer 120.

The electrically conductive filler 100 can be manufactured by coating core particles 110 having an average particle diameter (D50) of 0.01-100 μm with an intermediate layer 120 using, for example, plating, autoclave, or gas-phase technology (e.g., CVD). Preferably, the core particles 110 have an average particle diameter (D50) of 5-20 μm.

In embodiments, the core particles 110 are formed using a material having a low density, a high dielectric constant, and a low electrical resistance. In embodiments, the electrically conductive filler 100 is embedded in a resin. In embodiments, Ni/Cu/C is loaded in silicon rubber in a 60/30 ratio by weight to produce conductive adhesives or extruded gaskets, which will provide shielding performance >100 db in the 40-100 GHz range.

Preferably, the core particles 110 are formed using a material having a low density for the final composite particles to match the density of the resin. In one embodiment, the density of the material used for the core is 5 g/cm³ or less. In a preferred embodiment, the density of the material used for the core is less than 3 g/cm³. In a still preferred embodiment, the density of the material used for the core is less than 2.5 g/cm³. Some specific examples of materials suitable for the core in this disclosure include, but are not limited to, graphite having a density of 2.266 g/cm³, silicon carbide (SiC) having a density of 3.21 g/cm³, and titania (TiO₂) having a density of 4.23 g/cm³.

In embodiments, the core particles 110 have dielectric constant >10 which increases the shielding effectiveness of the core via absorption of incident electromagnetic waves. The dielectric constant is a dimensionless property and is defined as the ratio of the electric permeability of the material to the electric permeability in a vacuum. In one embodiment, the dielectric constant of the core particles 110 is 2 or greater. In preferred embodiments, the dielectric constant of the core particles 110 is 10 or greater. In still preferred embodiments, the dielectric constant of the core particles 110 is 10 or greater. Exemplary examples of core particles 110 include graphite having a dielectric constant of 10-15, titanium dioxide having a dielectric constant of 80-100 and silicon carbide having a dielectric constant of up to 10. In a preferred embodiment, the core particles 110 are composed of graphite.

In embodiments, the core particles 110 have a low electrical resistance by enhancing the adsorption of incident electromagnetic waves by the core material. In some embodiments, the core particles 110 have an electrical resistivity at or below 10 Ohm*m. Graphite, titanium dioxide, and silicon carbide each has an electrical resistivity in the range of 5×10⁻⁴ to 10 Ohm*m. In a preferred embodiment, the core particles 110 have low electrical resistivity of about 5×10⁻⁴ Ohm*m.

In embodiments, the intermediate layer 120 has a thickness of 0.05 to 10 μm, such as, for example, 1 to 2 μm. Preferably, the intermediate layer 120 has a thickness of 1 to 2 μm.

In embodiments, the intermediate layer 120 is generally described as a material having an improved electrical conductivity as compared to Nickel. In one embodiment, the intermediate layer 120 includes a material having an electrical conductivity of 5.90×10⁻⁸ Ohm*m or greater. In preferred embodiments, the intermediate layer 120 includes a material having an electrical conductivity of 3.36×10⁻⁸ Ohm*m or greater. In still preferred embodiments, the intermediate layer 120 includes a material having an electrical conductivity of 1.68×10⁻⁸ or greater. Exemplary materials of the intermediate layer 120 include Cu, Al, Zn, W. In a preferred embodiment, the intermediate layer 120 is copper.

The outer layer 130 is deposited onto the intermediate layer 120 using, for example, plating, autoclave, or gas-phase technology. In one embodiment, a relatively thin outer layer 130 in a range of 100 nm to 1 μm can be used to reduce density and, thus, the weight of the composite particle. In another embodiment, the thickness of the outer layer 130 can be increased to 100 nm to 4 μm to provide effective shielding across a low frequency range and in the GHz range. Preferably, the thickness of the outer layer 130 is in a range of 100 nm to 2 μm.

In some embodiments, the outer layer 130 is generally formed using a corrosion resistant alloy material having improved corrosion resistance as compared to copper. In one embodiment, a relatively thin corrosion resistant alloy (CRA) is deposited onto the intermediate layer 120 to further improve corrosion resistance. In one embodiment, the CRA layer deposited as the outer-layer 130 has a more noble galvanic potential in seawater than nickel as measured via ASTM G82. In some embodiments, the electrochemical potential of the alloy used for the outer layer 130 is −0.2 V vs. Ag/AgCl reference or greater. In some embodiments, the electrochemical—potential of the alloy used for the outer layer 130 is −0.1 V vs. Ag/AgCl reference or greater.

Some non-limiting alloys of materials which can be used for the outer layer 130 include, but are not limited to, Nickel, Nickel-Chromium alloys, NiMo, NiSi alloy, and Tungsten. In a preferred embodiment, the outer layer 130 is Nickel. In some embodiments, the outer layer 130 is formed via the pack diffusion process. In one embodiment, a nickel silicon layer is formed via pack diffusion of Si into Ni layer. In one embodiment, a relatively thin nickel silicon (Ni₃Si) layer in a range of 100 nm to 500 nm is formed via pack diffusion of nickel into Si layer.

In some embodiments, enhanced corrosion resistance is provided to the electrically conductive filler 100 without the use of known corrosion resistant elements which are expensive. In one embodiment, the use of silver is specifically avoided. In another embodiment, gold is specifically avoided. In yet another embodiment, platinum is specifically avoided.

Further, at least because the invention is disclosed herein in a manner that enables one to make and use it, by virtue of the disclosure of particular exemplary embodiments, such as for simplicity or efficiency, for example, the invention can be practiced in the absence of any additional element or additional structure that is not specifically disclosed herein.

It is noted that the foregoing examples have been provided merely for the purpose of explanation and are in no way to be construed as limiting of the present invention. While the present invention has been described with reference to an exemplary embodiment, it is understood that the words which have been used herein are words of description and illustration, rather than words of limitation. Changes may be made, within the purview of the appended claims, as presently stated and as amended, without departing from the scope and spirit of the present invention in its aspects. Although the present invention has been described herein with reference to particular means, materials and embodiments, the present invention is not intended to be limited to the particulars disclosed herein; rather, the present invention extends to all functionally equivalent structures, methods and uses, such as are within the scope of the appended claims.

What is claimed:

1. An electrically conductive composite powder for improving EMI shielding performance, comprising:
a core of particles formed from a material having a low density of <5 g/cm³ and a high dielectric constant of ≥10;
an intermediate layer coated onto the core of particles, wherein said intermediate layer has a high electrical conductivity >5.90×10⁻⁸ Ohm*m or greater at 20° C.; and
an outer layer that is deposited onto the intermediate layer, said outer layer comprising a material having a high corrosion resistance of >−0.2V galvanic potential in seawater as measured via ASTM G82 and oxidation resistance comparable to one of Ni or better.

2. The electrically conductive composite powder according to claim 1, wherein the core of particles is at least one selected from the group consisting of graphite, titanium dioxide and silicon carbide.

3. The electrically conductive composite powder according to claim 1, wherein the intermediate layer is copper.

4. The electrically conductive composite powder according to claim 1, wherein the core of particles has an average particle diameter (D50) of 0.01-100 μm.

5. The electrically conductive composite powder according to claim 1, wherein the intermediate layer has a thickness of 0.05 to 4 μm.

6. The electrically conductive composite powder for according to claim 5, wherein the intermediate layer has a thickness of 1 to 2 μm.

7. The electrically conductive composite powder according to claim 1, wherein the outer layer has a thickness of 100 to 500 nm.

8. The electrically conductive composite powder according to claim 1, wherein the intermediate layer is applied via plating, autoclave, or gas-phase technology.

9. The electrically conductive composite powder according to claim 1, wherein the outer layer is applied via plating, autoclave, or gas-phase technology.

10. The electrically conductive composite powder according to claim 1, wherein the outer layer is applied via pack diffusion of an element or elements into the outer layer.

11. A nickel coated graphite (Ni/C) based electrically conductive material for improving EMI shielding performance, comprising:
a graphite core of particles;
a copper layer coated onto the graphite core of particles; and
a nickel layer that is deposited onto the copper layer.

12. The nickel coated graphite based electrically conductive material according to claim 1, wherein the graphite core of particles has an average particle diameter (D50) of 0.01-100 μm.

13. The nickel coated graphite based electrically conductive material according to claim 1, wherein the copper layer has a thickness of 0.05 to 4 μm.

14. The nickel coated graphite based electrically conductive material according to claim 3, wherein the copper layer has a thickness of 1 to 2 μm.

15. A method for manufacturing an electrically conductive composite powder, comprising:
applying an intermediate layer having a high electrical conductivity of >5.90×10⁻⁸ Ohm*m at 20° C. onto a core of particles comprising a material having a low density of <5 g/cm³ and dielectric constant of ≥10; and
depositing an outer layer onto the intermediate layer, said outer layer comprising a material having a high oxidations and corrosion resistance of >−0.2V galvanic potential in seawater as measured via ASTM G82.

16. The method according to claim 15, wherein intermediate layer is applied onto the core of particles by plating, autoclave, or gas-phase technology.

17. The method according to claim 15, wherein outer layer is deposited onto the intermediate layer by plating, autoclave, or gas-phase technology.

18. The method according to claim 15, wherein outer layer is deposited onto the intermediate layer by pack diffusion of an element or elements into the intermediate layer.
